(19) United States
(12) Patent Application Publication
(10) Pub. No.: US 2021/0317581 A1
(43) Pub. Date: Oct. 14, 2021

(54) SUBSTRATE LIQUID PROCESSING APPARATUS AND SUBSTRATE LIQUID PROCESSING METHOD

(71) Applicant: Tokyo Electron Limited, Tokyo (JP)

(72) Inventors: Takafumi Niwa, Kikuchi-gun, Kumamoto (JP); Yuichiro Inatomi, Kikuchi-gun, Kumamoto (JP)

(21) Appl. No.: 17/264,472

(22) PCT Filed: Jul. 18, 2019
(86) PCT No.: PCT/JP2019/028319

§ 371 Date: Jan. 29, 2021

(30) Foreign Application Priority Data
Jul. 31, 2018 (JP) 2018-144088

(51) Int. Cl. C23C 18/16; C23C 18/54; H01L 21/67; H01L 21/768

(52) U.S. Cl. CPC C23C 18/1678; C23C 18/54; H01L 21/768; H01L 21/67098; C23C 18/163

(57) ABSTRACT

A substrate liquid processing apparatus includes a substrate holder 52 configured to attract, hold and rotate a substrate W; a heating device configured to heat the substrate holder 52 from an outside thereof; a plating liquid supply 53 configured to supply a plating liquid L1 onto the substrate W being rotated while being held by the substrate holder 52; and a controller 3 configured to control operations of the substrate holder 52, the heating device and the plating liquid supply 53. The controller 3 controls the heating device to heat the substrate holder 52 to equal to or higher than 50° C. before the substrate W is held by the substrate holder 52.

### TECHNICAL FIELD

The various aspects and embodiments described herein pertain generally to a substrate liquid processing apparatus and a substrate liquid processing method.

### BACKGROUND

Patent Document 1 describes a substrate liquid processing apparatus configured to perform an electroless plating processing on a substrate (wafer) by using a processing liquid composed of a plating liquid.

### PRIOR ART DOCUMENT

Patent Document 1: Japanese Patent Laid-open Publication No. 2018-003097

### DISCLOSURE OF THE INVENTION

### Problems to be Solved by the Invention

Exemplary embodiments provide a technique capable of improving uniformity of a plating film within a surface of a substrate in an electroless plating processing.

### Means for Solving the Problems

In an exemplary embodiment, a substrate liquid processing apparatus includes a substrate holder configured to attract, hold and rotate a substrate; a heating device configured to heat the substrate holder from an outside thereof; a plating liquid supply configured to supply a plating liquid onto the substrate being rotated while being held by the substrate holder; and a controller configured to control operations of the substrate holder, the heating device and the plating liquid supply. The controller controls the heating device to heat the substrate holder to equal to or higher than 50° C. before the substrate is held by the substrate holder.

### Effect of the Invention

According to the exemplary embodiments, it is possible to improve uniformity of the plating film within the surface of the substrate in the electroless plating processing.

### BRIEF DESCRIPTION OF THE DRAWINGS

FIG. 1 is a schematic plan view illustrating a configuration of a plating apparatus.

FIG. 2 is a schematic cross sectional view illustrating a configuration of a plating device shown in FIG. 1.

FIG. 3 is a flowchart illustrating a sequence of a plating processing upon a substrate in the plating apparatus of FIG. 1.

### DETAILED DESCRIPTION

Hereinafter, exemplary embodiments of the present disclosure will be described with reference to the accompanying drawings which form a part hereof.

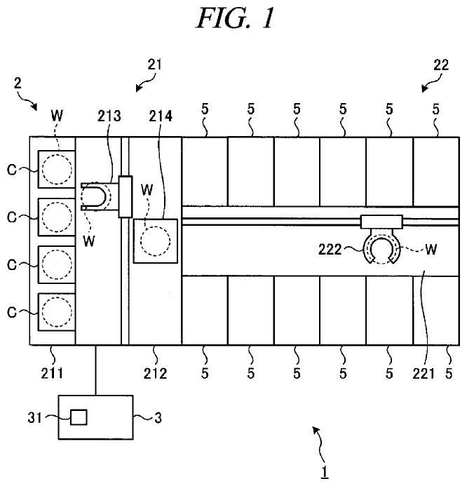

First, referring to FIG. 1, a configuration of a substrate liquid processing apparatus according to an exemplary embodiment will be described. FIG. 1 is a schematic plan view illustrating a configuration of a plating apparatus as an example of the substrate liquid processing apparatus according to the exemplary embodiment of the present disclosure. Here, the plating apparatus is an apparatus configured to perform a plating processing (liquid processing) on a substrate W by supplying a plating liquid L1 (processing liquid) onto the substrate W.

As depicted in FIG. 1, a plating apparatus 1 according to the present exemplary embodiment is equipped with a plating unit 2 and a controller 3 configured to control an operation of the plating unit 2.

The plating unit 2 is configured to perform various processings on the substrate W (wafer). The various processings performed by the plating unit 2 will be described later.

The controller 3 is implemented by, for example, a computer, and includes an operation controller and a storage. The operation controller is implemented by, by way of example, a CPU (Central Processing Unit) and is configured to control an operation of the plating unit 2 by reading and executing programs stored in the storage. The storage may be implemented by a memory device such as, but not limited to, a RAM (Random Access Memory), a ROM (Read Only Memory), or a hard disk, and stores therein programs for controlling the various processings performed in the plating unit 2.

The programs may be recorded in a computer-readable recording medium 31, or may be installed from the recording medium 31 to the storage. The computer-readable recording medium 31 may be, by way non-limiting example, a hard disk (HD), a flexible disk (FD), a compact disk (CD), a magnet optical disk (MO), or a memory card. Stored in the recording medium 31 is a program which, when executed by a computer for controlling the operation of the plating apparatus 1, allows the computer to control the plating apparatus 1 to perform a plating method to be described later.

Referring to FIG. 1, a configuration of the plating unit 2 will be elaborated. FIG. 1 is a schematic plan view illustrating the configuration of the plating unit 2.

The plating unit 2 includes a carry-in/out station 21 and a processing station 22 which is provided adjacent to the carry-in/out station 21.

The carry-in/out station 21 is equipped with a placing section 211 and a transfer section 212 which is provided adjacent to the placing section 211.

In the placing section 211, transfer containers (hereinafter, referred to as “carriers C”) for accommodating therein a plurality of substrates W horizontally are placed.

The transfer section 212 is equipped with a transfer device 213 and a delivery unit 214. The transfer device 213 is provided with a holding mechanism configured to hold a substrate W and is configured to be movable horizontally and vertically and pivotable around a vertical axis.

The processing station 22 includes plating devices 5. In the present exemplary embodiment, the number of the plating devices 5 belonging to the processing station 22 is two or more. However, only one plating device 5 may be provided. The plating devices 5 are arranged at both sides (both sides in a direction perpendicular to a moving direction of a transfer device 222 to be described below) of a transfer path 221 which extends in a preset direction.

The transfer device 222 is provided in the transfer path 221. The transfer device 222 is equipped with a holding mechanism configured to hold the substrate W and is configured to be movable horizontally and vertically and pivotable around a vertical axis.

In the plating unit 2, the transfer device 213 of the carry-in/out station 21 is configured to transfer the substrate W between the carrier C and the delivery unit 214. To elaborate, the transfer device 213 takes out the substrate W from the carrier C which is placed in the placing section 211, and places the substrate W in the delivery unit 214. Further, the transfer device 213 takes out the substrate W which is placed in the delivery unit 214 by the transfer device 222 of the processing station 22, and stores the substrate W back into the carrier C on the placing section 211.

In the plating unit 2, the transfer device 222 of the processing station 22 is configured to transfer the substrate W between the delivery unit 214 and the plating device 5 and between the plating device 5 and the delivery unit 214. To elaborate, the transfer device 222 takes out the substrate W which is placed in the delivery unit 214 and then carries the substrate W into the plating device 5. Further, the transfer device 222 takes out the substrate W from the plating device 5 and places the substrate W in the delivery unit 214.

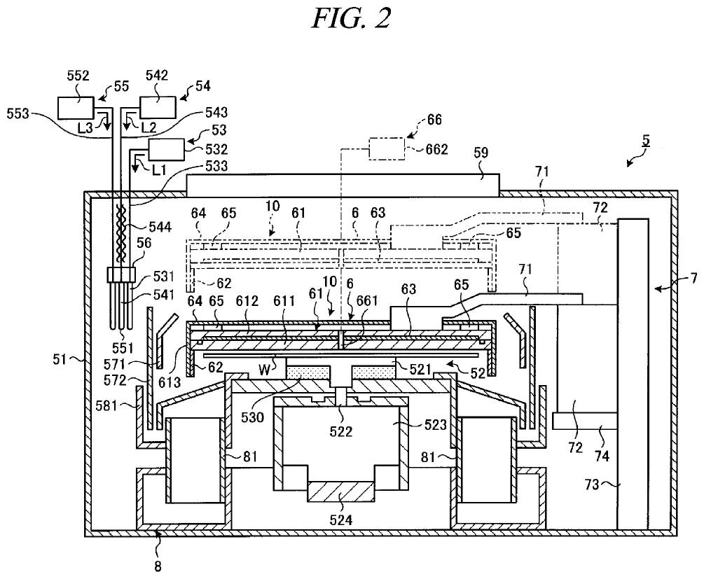

Now, a configuration of the plating device 5 will be described with reference to FIG. 2. FIG. 2 is a schematic cross sectional view illustrating the configuration of the plating device 5.

The plating device 5 is configured to perform the liquid processing including an electroless plating processing. This plating device 5 includes a chamber 51; a substrate holder 52 provided within the chamber 51 and configured to hold the substrate W horizontally; and a plating liquid supply 53 (processing liquid supply) configured to supply the plating liquid L1 (processing liquid) onto a top surface of the substrate W held by the substrate holder 52.

In the present exemplary embodiment, the substrate holder 52 includes a chuck member 521 configured to vacuum-attract a bottom surface (rear surface) of the substrate W. This chuck member 521 is of a so-called vacuum chuck type.

The substrate holder 52 is connected with a rotation motor 523 (rotational driving unit) via a rotation shaft 522. If the rotation motor 523 is driven, the substrate holder 52 is rotated along with the substrate W. The rotation motor 523 is supported on a base 524 which is fixed to the chamber 51. Further, a heating source such as a heater is not provided within the substrate holder 52.

The plating liquid supply 53 is equipped with a plating liquid nozzle 531 (processing liquid nozzle) configured to discharge (supply) the plating liquid L1 onto the substrate W held by the substrate holder 52; and a plating liquid source 532 configured to supply the plating liquid L1 to the plating liquid nozzle 531. The plating liquid source 532 is configured to supply the plating liquid L1 heated to or regulated to a preset temperature to the plating liquid nozzle 531 through a plating liquid line 533. A temperature of the plating liquid L1 at the moment when it is discharged from the plating liquid nozzle 531 is in a range from, e.g., 55° C. to 75° C., more desirably, in a range from 60° C. to 70° C. The plating liquid nozzle 531 is held by a nozzle arm 56 and configured to be movable.

The plating liquid L1 is an autocatalytic (reduction) plating liquid for electroless plating. The plating liquid L1 contains, for example, a metal ion and a reducing agent. The metal ion included in the plating liquid L1 is, by way of example, but not limitation, a cobalt (Co) ion, a nickel (Ni) ion, a tungsten (W) ion; a copper (Cu) ion, a palladium (Pd) ion, a gold (Au) ion, a ruthenium (Ru) ion, or the like. Further, the reducing agent included in the plating liquid L1 is, by way of non-limiting example, hypophosphorous acid, dimethylamineborane, glyoxylic acid, or the like. The plating liquid L1 may further contain an additive or the like. A plating film formed by the plating processing using the plating liquid L1 may be, by way of non-limiting example, CoWB, CoB, CoWP, CoWBP, NiWB, NiB, NiWP, NiWBP, Cu, Pd, Ru, or the like. Further, the plating film may be formed to have a monolayer, or to have two or more layers. When the plating film has a double-layer structure, it may have a layer combination of, for example, CoWB/CoB or Pd/CoB in sequence from a base metal layer side.

The plating device 5 is further equipped with a pre-cleaning liquid supply 54 configured to supply a pre-cleaning liquid L2 onto the top surface of the substrate W held by the substrate holder 52; and a rinse liquid supply 55 configured to supply a rinse liquid L3 onto the top surface of the substrate W.

The pre-cleaning liquid supply 54 supplies the pre-cleaning liquid L2 onto the substrate W which is rotated while being held by the substrate holder 52, and performs a pre-cleaning processing on a base metal layer of the substrate W. This pre-cleaning liquid supply 54 is equipped with a pre-cleaning liquid nozzle 541 configured to discharge the pre-cleaning liquid L2 onto the substrate W held by the substrate holder 52; and a pre-cleaning liquid source 542 configured to supply the pre-cleaning liquid L2 to the pre-cleaning liquid nozzle 541. Here, the pre-cleaning liquid source 542 is configured to supply the pre-cleaning liquid L2, which is heated to or regulated to a predetermined temperature as will be described later, to the pre-cleaning liquid nozzle 541 through a pre-cleaning liquid line 543. The pre-cleaning liquid nozzle 541 is held by the nozzle arm 56, and configured to be movable along with the plating liquid nozzle 531.

As an example of the pre-cleaning liquid L2, dicarboxylic acid or tricarboxylic acid may be used. As an example of the dicarboxylic acid, an organic acid such as a malic acid, a succinic acid, a malonic acid, an oxalic acid, a glutaric acid, an adipic acid, or a tartaric acid may be used. Further, as an example of the tricarboxylic acid, an organic acid such as a citric acid may be used.

The pre-cleaning liquid L2 at least on the substrate W is heated to or regulated to a temperature higher than a room temperature. To elaborate, the temperature of the pre-cleaning liquid L2 is equal to or higher than 40° C.; desirably, falls within a range from 50° C. to 80° C.; and, more desirably, falls within a range from 60° C. to 70° C. By heating or regulating the pre-cleaning liquid L2 to the temperature equal to or higher than 40° C., reactivity of the pre-cleaning liquid L2 can be improved, and an oxide film or the like formed on the base metal layer of the substrate W can be removed efficiently in a short time.

The pre-cleaning liquid L2 is heated by a heating device 544 of the pre-cleaning liquid supply 54. In this case, the heating device 544 is a heat exchanger provided at the pre-cleaning liquid line 543, and heats the pre-cleaning liquid L2 flowing in the pre-cleaning liquid line 543. However, the present exemplary embodiment is not limited thereto, and the heating device 544 may be provided in a tank of the pre-cleaning liquid source 542 to heat the pre-cleaning liquid L2 filled in the tank. In this case, the temperature of the pre-cleaning liquid L2 at the moment when it is supplied onto the substrate W from the pre-cleaning liquid nozzle 541 may be set to be equal to or higher than 40° C. Alternatively, the pre-cleaning liquid L2 may be supplied from the pre-cleaning liquid nozzle 541 onto the substrate W in a room-temperature state, and then, the temperature of the pre-cleaning liquid L2 on the substrate W is heated to equal to or higher than 40° C. by a heating device (for example, a heater 63 to be described later) provided near the substrate W.

Furthermore, it is desirable to set the temperature of the pre-cleaning liquid L2 to be close to the temperature of the plating liquid L1 to be used in a subsequent process. To elaborate, it is desirable to set the temperature of the pre-cleaning liquid L2 to be within a range of ±5° C. of the temperature of the plating liquid L1. By way of example, when the temperature of the plating liquid L1 at the moment when it is discharged is in a range from 55° C. to 75° C., it is desirable that the temperature of the pre-cleaning liquid L2 is set to be in a range from 50° C. to 80° C. In this way, by setting the temperature of the pre-cleaning liquid L2 to be close to the temperature of the plating liquid L1, the substrate W can be pre-heated by the pre-cleaning liquid L2 before the plating processing is performed. Thus, the plating processing can be begun smoothly.

The rinse liquid supply 55 is equipped with a rinse liquid nozzle 551 configured to discharge the rinse liquid L3 onto the substrate W held by the substrate holder 52; and a rinse liquid source 552 configured to supply the rinse liquid L3 to the rinse liquid nozzle 551. The rinse liquid nozzle 551 is held by the nozzle arm 56 and configured to be movable along with the plating liquid nozzle 531 and the pre-cleaning liquid nozzle 541. Further, the rinse liquid source 552 is configured to supply the rinse liquid L3 to the rinse liquid nozzle 551 through a rinse liquid line 553. As an example of the rinse liquid L3, pure water or the like may be used.

A non-illustrated nozzle moving device is connected to the nozzle arm 56 which holds the plating liquid nozzle 531, the pre-cleaning liquid nozzle 541 and the rinse liquid nozzle 551. This nozzle moving device is configured to move the nozzle arm 56 horizontally and vertically. To be more specific, the nozzle arm 56 is configured to be moved between a discharge position where the processing liquid (the plating liquid L1, the pre-cleaning liquid L2 or the rinse liquid L3) is discharged onto the substrate W and a retreat position where the nozzle arm 56 is retreated from the discharge position. Here, the discharge position is not particularly limited as long as the processing liquid can be supplied onto a certain position on the top surface of the substrate W. By way of example, appropriately, the discharge position may be set such that the processing liquid can be supplied onto a center of the substrate W. The discharge position of the nozzle arm 56 may be different when the plating liquid L1 is supplied onto the substrate W, when the pre-cleaning liquid L2 is supplied onto the substrate W, and when the rinse liquid L3 is supplied onto the substrate W. The retreat position is a position within the chamber 51 which is not overlapped with the substrate W when viewed from above and is far from the discharge position. When the nozzle arm 56 is placed at the retreat position, interference between this nozzle arm 56 and a cover body 6 being moved can be avoided.

A cup 571 is disposed around the substrate holder 52. The cup 571 has a ring shape when viewed from above. The cup 571 receives the processing liquid scattered from the substrate W when the substrate W is rotated, and guides the received processing liquid to a drain duct 581. An atmosphere blocking cover 572 is provided at an outside of the cup 571 to suppress diffusion of an atmosphere around the substrate W into the chamber 51. This atmosphere blocking cover 572 has a cylindrical shape vertically extending with an open top. The cover body 6 to be described later is configured to be inserted into the atmosphere blocking cover 572 from above.

In the present exemplary embodiment, the substrate W held by the substrate holder 52 is covered by the cover body 6. This cover body 6 includes a ceiling member 61 and a sidewall member 62 extending downwards from the ceiling member 61.

The ceiling member 61 includes a first ceiling plate 611 and a second ceiling plate 612 provided on the first ceiling plate 611. A heater 63 (heating device) is disposed between the first ceiling plate 611 and the second ceiling plate 612. The first ceiling plate 611 and the second ceiling plate 612 are configured to seal the heater 63 lest the heater 63 should come into contact with the processing liquid such as the plating liquid L1. To be more specific, a seal ring 613 is disposed at an outside of the heater 63 between the first ceiling plate 611 and the second ceiling plate 612, and the heater 63 is sealed by this seal ring 613. Appropriately, the first ceiling plate 611 and the second ceiling plate 612 have corrosion resistance against the processing liquid such as the plating liquid L1, and may be made of, by way of non-limiting example, an aluminium alloy. Further, to improve the corrosion resistance, the first ceiling plate 611, the second ceiling plate 612 and the sidewall member 62 may be coated with Teflon (registered trademark).

The cover body 6 is connected with a cover body moving device 7 via a cover body arm 71. The cover body moving device 7 is configured to move the cover body 6 horizontally and vertically. To be more specific, the cover body moving device 7 includes a turning motor 72 configured to move the cover body 6 horizontally and a cylinder 73 (distance adjuster) configured to move the cover body 6 vertically. The turning motor 72 is mounted on a supporting plate 74 configured to be movable vertically with respect to the cylinder 73. As an alternative to the cylinder 73, an actuator (not shown) including a motor and a ball screw may be used.

The turning motor 72 of the cover body moving device 7 is configured to move the cover body 6 between an upper position above the substrate W held by the substrate holder 52 and a retreat position retreated from the upper position. Here, the upper position is a position facing the substrate W held by the substrate holder 52 with a relatively large gap therebetween and overlapped with the substrate W when viewed from above. The retreat position is a position within the chamber 51 which is not overlapped with the substrate W when viewed from above. When the cover body 6 is located at the retreat position, interference between the nozzle arm 56 being moved and the cover body 6 is avoided. A rotational axis of the turning motor 72 extends vertically, and the cover body 6 is configured to be rotatable horizontally between the upper position and the retreat position.

The cylinder 73 of the cover body moving device 7 is configured to move the cover body 6 up and down to thereby adjust a distance between the first ceiling plate 611 of the ceiling member 61 and the substrate Won which the plating liquid L1 is supplied. To be more specific, the cylinder 73 locates the cover body 6 at a lower position (a position indicated by a solid line in FIG. 2) or the upper position (a position indicated by a dashed double-dotted line in FIG. 2).

In the present exemplary embodiment, if the cover body 6 is placed at the aforementioned lower position, the heater is driven 63 to heat the substrate holder 52 or the plating liquid L1 on the substrate W.

In the present exemplary embodiment, an inert gas (for example, a nitrogen (N₂) gas) is supplied to an inside of the cover body 6 by an inert gas supply 66. The inert gas supply 66 is equipped with a gas nozzle 661 configured to discharge the inert gas to the inside of the cover body 6; and an inert gas source 662 configured to supply the inert gas to the gas nozzle 661. The gas nozzle 661 is provided at the ceiling member 61 of the cover body 6 and is configured to discharge the inert gas toward the substrate W in the state that the cover body 6 covers the substrate W.

The ceiling member 61 and the sidewall member 62 of the cover body 6 are covered by a cover body lid 64. This cover body lid 64 is disposed on the second ceiling plate 612 of the cover body 6 with supporting members 65 therebetween. That is, the second ceiling plate 612 is provided with the multiple supporting members 65 protruding upwards from a top surface of the second ceiling plate 612, and the cover body lid 64 is placed on the supporting members 65. The cover body lid 64 is configured to be moved horizontally and vertically along with the cover body 6. Further, it is desirable that the cover body lid 64 has insulation property higher than those of the ceiling member 61 and the sidewall member 62 to suppress a leak of heat within the cover body 6 to the vicinity thereof. By way of example, the cover body lid 64 is desirably made of a resin material, and, more desirably, the resin material has heat resistance.

As described above, in the present exemplary embodiment, the cover body lid 64 and the cover body 6 equipped with the heater 63 are configured as one body. This cover body 6 and the cover body lid 64 constitute a cover unit 10 which covers the substrate holder 52 or the substrate W when placed at the lower position.

A fan filter unit 59 (gas supply) is provided at an upper portion of the chamber 51 to supply clean air (gas) to the vicinity of the cover body 6. The fan filter unit 59 is configured to supply the air into the chamber 51 (particularly, into the atmosphere blocking cover 572), and the supplied air flows toward exhaust pipes 81. A downflow of the air flowing downwards is formed around the cover body 6, and a gas vaporized from the processing liquid such as the plating liquid L1 flows toward the exhaust pipes 81 by being carried by this downflow. Accordingly, a rise of the gas vaporized from the processing liquid and diffusion of this gas into the chamber 51 are suppressed.

The gas supplied from the above-described fan filter unit 59 is exhausted by an exhaust device 8.

In the plating device 5 of the plating apparatus 1 having the above-described configuration, operations of the substrate holder 52, the heater 63 (heating device) and the plating liquid supply 53 are controlled by the controller 3. The controller 3 controls the heater 63 (heating device) to heat the substrate holder 52 to equal to or higher than 50° C. before the substrate W is attracted to and held by the substrate holder 52. By way of example, if the temperature of the plating liquid L1 at the moment when it is discharged is in the range from 55° C. to 75° C., it is desirable that the temperature of the substrate holder 52 is set to be in the range from 50° C. to 80° C.

In the above description, though the substrate holder 52 is heated by the heater 63 (heating device) provided above the substrate holder 52, the exemplary embodiment is not limited thereto, and the substrate holder 52 may be heated by, for example, an annular heater 530 (heating device) which is provided under the substrate holder 52.

Moreover, when the substrate holder 52 is heated by the annular heater 530 (heating device), the cover body 6 equipped with the heater 63 may be located at the upper position above the substrate W held by the substrate holder 52, or located at the retreat position retreated from the upper position. Accordingly, a time taken to move the cover body 6 equipped with the heater 63 to the lower position where the heater 63 heats the substrate holder 52 can be omitted.

Furthermore, without being limited to the above description, the cover body 6 having the heater 63 may be moved to the lower position where the heater 63 heats the substrate holder 52, and the substrate holder 52 may be heated by both the heater 63 and the annular heater 530 (heating device) at the same time. In this case, the substrate holder 52 can be heated rapidly. Further, the substrate holder 52 can be heated even in the middle of the plating processing.

Conventionally, a decrease of the temperature of the plating liquid L1 on the substrate W may be caused due to heat absorption by the substrate holder 52 when the substrate W is attracted to and held by the substrate holder 52. In such a case, growth of the plating film may be impeded. As a result, the plating film formed on a region of the substrate W corresponding to the substrate holder 52 may be thinned, so that the film thickness of the plating film may become non-uniform within the surface of the substrate W.

In the present exemplary embodiment, the controller 3 controls the heater 63 (heating device) to heat the substrate holder 52 to equal to or higher than 50° C. before the substrate W is attracted to and held by the substrate holder 52. By way of example, when the temperature of the plating liquid L1 at the moment when it is discharged is in the range from 55° C. to 75° C., it is desirable that the temperature of the substrate holder 52 is set to be in the range from 50° C. to 80° C. Accordingly, the heat absorption by the substrate holder 52 is suppressed, so that uniformity of the plating film within the surface of the substrate W can be improved.

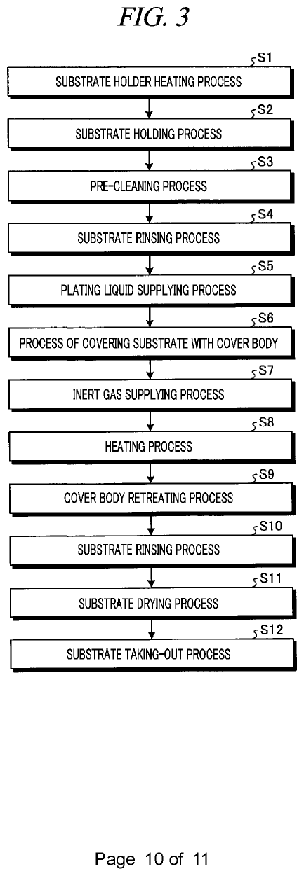

Now, an operation of the present exemplary embodiment having the above-described configuration will be explained with reference to FIG. 3. Here, a plating method using the plating apparatus 1 will be described as an example of a substrate liquid processing method.

The plating method performed by the plating apparatus 1 includes a plating processing upon the above-described substrate W. The plating processing is performed by the plating device 5. An operation of the plating device 5 to be described below is controlled by the controller 3. Further, while the following processing is being performed, clean air is supplied into the chamber 51 from the fan filter unit 59 and flows toward the exhaust pipes 81.

[Substrate Holding/Heating Process]

First, the substrate holder 52 is covered by the cover body 6 equipped with the heater 63 (heating device), and the substrate holder 52 is heated (process S1). In this case, the turning motor 72 of the cover body moving device 7 is first driven to allow the cover body 6 located at the retreat position to be rotated and placed at the upper position. Then, the cylinder 73 of the cover body moving device 7 is driven to lower the cover body 6 located at the upper position. Accordingly, the substrate holder 52 is covered by the cover body 6, and the heater 63 (heating device) is driven to heat the substrate holder 52. In this substrate holding/heating process, the substrate holder 52 is heated to a heating temperature equal to or higher than 50° C. For example, if the temperature of the plating liquid L1 at the moment when it is discharged is in the range from 55° C. to 75° C., it is desirable to set the temperature of the substrate holder 52 to be in the range from 50° C. to 80° C.

[Substrate Holding Process]

Subsequently, the substrate W is carried into the plating device 5, and the carried substrate W is held by the substrate holder 52 (process S2). Here, the bottom surface of the substrate W is vacuum-attracted, and the substrate W is horizontally held by the substrate holder 52.

[Pre-Cleaning Process]

Thereafter, the substrate W horizontally held by the substrate holder 52 is subjected to a pre-cleaning processing (process S3). In this case, the rotation motor 523 is first driven to rotate the substrate W at a preset rotation number. Then, the nozzle arm 56 located at the retreat position is moved to the discharge position. Thereafter, the pre-cleaning liquid L2 is supplied from the pre-cleaning liquid nozzle 541 onto the substrate W being rotated, so that the surface of the substrate W is cleaned. Accordingly, the oxide film, the deposit, or the like formed on the surface of the substrate W is removed from the substrate W. The pre-cleaning liquid L2 supplied onto the substrate W is drained into the drain duct 581.

[Substrate Rinsing Process]

Subsequently, the cleaned substrate W is subjected to a rinsing processing (process S4). In this rinsing processing, the rinse liquid L3 is supplied from the rinse liquid nozzle 551 onto the substrate W being rotated, so that the surface of the substrate W is rinsed. Accordingly, the pre-cleaning liquid L2 remaining on the substrate W is washed away. The rinse liquid L3 supplied onto the substrate W is drained into the drain duct 581. Here, a temperature of the rinse liquid L3 may not be limited to a room temperature, and the rinse liquid L3 may be heated by a heating device (not shown) provided in the rinse liquid supply 55 to a temperature equal to or higher than the temperature at which the plating liquid L1 is heated.

[Plating Liquid Supplying Process]

Afterwards, as a plating liquid supplying process, the plating liquid L1 is supplied to be accumulated on the rinsed substrate W (process S5). In this case, the rotation number of the substrate W is reduced to be smaller than a rotation number in the rinsing processing. By way of example, the rotation number of the substrate W may be set to be in a range from 50 rpm to 150 rpm. Accordingly, a plating film to be described later, which is formed on the substrate W, can be uniformed. Further, in order to increase an accumulation amount of the plating liquid L1, the rotation of the substrate W may be stopped.

Subsequently, the plating liquid L1 is discharged onto the top surface of the substrate W from the plating liquid nozzle 531. The discharged plating liquid L1 stays on the top surface of the substrate W due to a surface tension. Accordingly, the plating liquid L1 is accumulated on the top surface of the substrate W, and a layer (a so-called puddle) of the plating liquid L1 is formed. A part of the plating liquid L1 flows out from the top surface of the substrate W to be drained through the drain duct 581. After a preset amount of the plating liquid L1 is discharged from the plating liquid nozzle 531, the discharge of the plating liquid L1 is stopped. Then, the nozzle arm 56 placed at the discharge position is moved to the retreat position.

[Plating Liquid Heating Process]

Next, as a plating liquid heating process, the plating liquid L1 accumulated on the substrate W is heated. This plating liquid heating process includes a process of covering the substrate W with the cover body 6 (process S6), a process of supplying the inert gas (process S7), a process of heating the plating liquid L1 (process S8). Further, it is desirable that the rotation number of the substrate W in this plating liquid heating process is maintained equal to the rotation number in the plating liquid supplying process (or the rotation of the substrate W is stopped).

<Process of Covering Substrate with Cover Body>

First, the substrate W is covered with the cover body 6 (process S6). In this case, the turning motor 72 of the cover body moving device 7 is first driven to allow the cover body 6 placed at the retreat position to be rotated to the upper position. Then, the cylinder 73 of the cover body moving device 7 is driven to lower the cover body 6 placed at the upper position. Accordingly, the substrate W is covered by the cover body 6, and a space around the substrate W is closed.

<Inert Gas Supplying Process>

After the substrate W is covered by the cover body 6, the gas nozzle 661 provided at the ceiling member 61 of the cover body 6 discharges the inert gas to the inside of the cover body 6 (process S7). Accordingly, an atmosphere inside the cover body 6 is replaced by the inert gas, so that the space around the substrate W is turned into a low-oxygen atmosphere. The inert gas is discharged for a predetermined time, and the discharge of the inert gas is then stopped.

<Heating Process>

Thereafter, the plating liquid L1 accumulated on the substrate W is heated (process S8). In the heating process, the heater 63 is driven to heat the plating liquid L1 accumulated on the substrate W. The heating of the plating liquid L1 in the heating process is performed for a preset time so that the temperature of the plating liquid L1 reaches the predetermined temperature. If the temperature of the plating liquid L1 reaches a temperature where a component of the plating liquid L1 is precipitated, the component of the plating liquid L1 is precipitated on the top surface of the substrate W, and the plating film starts to grow on the top surface of the substrate W.

<Cover Body Retreating Process>

Upon the completion of the heating process, the cover body moving device 7 is driven to locate the cover body 6 to the retreat position (process S9). In this case, the cylinder 73 of the cover body moving device 7 is driven to raise the cover body 6 to the upper position. Then, the turning motor 72 of the cover body moving device 7 is driven to allow the cover body 6 placed at the upper position to be rotated horizontally and located at the retreat position.

Through these operations, the plating liquid heating process (the processes S6 to S9) upon the substrate W is completed.

[Substrate Rinsing Process]

Subsequently, the substrate W after being subjected to the plating liquid heating process is subjected to a rinsing process (process S10). In this case, the rotation number of the substrate W is first increased to be higher than the rotation number in the plating processing. By way of example, the substrate W is rotated at the same rotation number as in the substrate rinsing process (process S4) before the plating processing. Then, the rinse liquid nozzle 551 placed at the retreat position is moved to the discharge position. Next, the rinse liquid L3 is supplied from the rinse liquid nozzle 551 onto the substrate W being rotated, so that the surface of the substrate W is cleaned, and the plating liquid L1 remaining on the substrate W is washed away.

[Substrate Drying Process]

Thereafter, the rinsed substrate W is subjected to a drying processing (process S11). In this case, the rotation number of the substrate W is increased to be higher than, for example, the rotation number in the substrate rinsing process (process S10) to rotate the substrate W at a high speed. Accordingly, the rinse liquid L3 remaining on the substrate W is removed by being scattered, and the substrate W having the plating film formed thereon is obtained. In this case, the drying of the substrate W may be accelerated by discharging the inert gas such as the nitrogen (N₂) gas onto the substrate W. Further, in the substrate rinsing process (process S10), a processing liquid composed of an organic solvent such as IPA (Isopropyl Alcohol) may be supplied onto the substrate W. At this time, the rinse liquid L3 remaining on the substrate W may be mixed into the processing liquid such as the IPA, and by scattering and evaporating this processing liquid off the substrate W, the substrate W may be dried.

[Substrate Taking-Out Process]

Afterwards, the substrate W is taken out from the substrate holder 52 and carried out from the plating device 5 (process S12).

Through the above-stated operations, the series of processes of the plating method (the processes S1 to S12) upon the substrate W using the plating apparatus 1 are completed.

According to the present exemplary embodiment as described above, in performing the plating processing by supplying the plating liquid L1 onto the substrate W while attracting/holding and rotating the substrate W horizontally, the substrate holder 52 configured to attract and hold the substrate W is heated from the outside thereof. The heating of the substrate holder 52 is performed before the substrate holder 52 holds the substrate W, and the temperature of the substrate holder 52 is set to be equal to or higher than 50° C.

In the above-described exemplary embodiment, though the substrate holder 52 is heated by the heater 63 (heating device) disposed above the substrate holder 52, the exemplary embodiment is not limited thereto, and the substrate holder 52 may be heated by, for example, the annular heater 530 (heating device) provided under the substrate holder 52.

Further, when the substrate holder 52 is heated by the annular heater 530 (heating device), the cover body 6 equipped with the heater 63 may be located at the upper position above the substrate W held by the substrate holder 52, or may be the retreat position retreated from the upper position.

In this case, the time taken to move the cover body 6 equipped with the heater 63 to the lower position where the heater 63 heats the substrate holder 52 can be omitted.

Moreover, without being limited to the above description, the cover body 6 having the heater 63 may be moved to the lower position where the heater 63 heats the substrate holder 52, and the substrate holder 52 may be heated by the heater 63 and the annular heater 530 (heating device) at the same time. Accordingly, the substrate holder 52 can be heated rapidly. Furthermore, the substrate holder 52 can be heated even in the middle of the plating processing.

Conventionally, a decrease of the temperature of the plating liquid L1 on the substrate W may be caused due to the heat absorption by the substrate holder 52 when the substrate W is attracted to and held by the substrate holder 52. In such a case, the growth of the plating film may be impeded. As a result, the plating film formed on the region of the substrate W corresponding to the substrate holder 52 may be thinned, so that the film thickness of the plating film may become non-uniform within the surface of the substrate W.

In the present exemplary embodiment, the controller 3 controls the heater 63 (heating device) to heat the substrate holder 52 to be equal to or higher than 50° C. before the substrate W is attracted to and held by the substrate holder 52. By way of example, when the temperature of the plating liquid L1 at the moment when it is discharged is in the range from 55° C. to 75° C., it is desirable that the temperature of the substrate holder 52 is set to be in the range from 50° C. to 80° C. Accordingly, the heat absorption by the substrate holder 52 is suppressed, so that the uniformity of the plating film within the surface of the substrate W can be improved.

The various exemplary embodiments and modification examples are not limiting and can be modified in various ways without departing from the technical conception and essence of the present disclosure. Further, the constituent components described in the above exemplary embodiments and modification examples may be combined appropriately to produce various other embodiments. Some of the constituent components described in the various exemplary embodiments and modification examples may be deleted in various ways. Further, the constituent components in the different exemplary embodiments and modification examples may be appropriately combined.

By way of example, the heater 530 (heating device) may be a lamp. Further, when the substrate holder 52 is heated with the cover body 6 equipped with the heater 63, a distance between the heater 63 and the substrate holder 52 and a heating time may be set as required to allow the substrate holder 52 to reach the required temperature.

### EXPLANATION OF CODES

1: Plating apparatus
2: Plating unit
3: Controller
10: Cover unit
31: Recording medium
5: Plating device
51: Chamber
52: Substrate holder
53: Plating liquid supply
54: Pre-cleaning liquid supply
63: Heater
530: Heater
541: Pre-cleaning liquid nozzle
542: Pre-cleaning liquid source
544: Heating device
55: Rinse liquid supply
56: Nozzle arm

1. A substrate liquid processing apparatus, comprising:
a substrate holder configured to attract, hold and rotate a substrate;
a heating device configured to heat the substrate holder from an outside thereof;
a plating liquid supply configured to supply a plating liquid onto the substrate being rotated while being held by the substrate holder; and
a controller configured to control operations of the substrate holder, the heating device and the plating liquid supply,
wherein the controller controls the heating device to heat the substrate holder to equal to or higher than 50° C. before the substrate is held by the substrate holder.

2. The substrate liquid processing apparatus of claim 1,
wherein the heating device is disposed above the substrate holder.

3. The substrate liquid processing apparatus of claim 2,
wherein the heating device is a cover unit equipped with a heater and configured to be placed at a lower position where the cover unit covers the substrate holder or the substrate.

4. The substrate liquid processing apparatus of claim 1,
wherein the heating device is provided under the substrate holder.

5. The substrate liquid processing apparatus of claim 4,
wherein the heating device comprises a heater or a lamp provided at an inner side than an edge of the substrate holder.

6. The substrate liquid processing apparatus of claim 1,
wherein a temperature of the heating device is equal to or lower than 80° C.

7. A substrate liquid processing method, comprising:
heating a substrate holder, which is configured to attract and hold a substrate, from an outside thereof;
holding the substrate by the substrate holder; and
performing a plating processing on the substrate by supplying a plating liquid onto the substrate while holding and rotating the substrate horizontally,
wherein in the heating of the substrate holder, the substrate holder is heated to equal to or higher than 50° C. before the substrate is held by the substrate holder.

8. The substrate liquid processing method of claim 7,
wherein a heating device in the heating of the substrate holder is disposed at either an upper position above the substrate holder or a lower position under the substrate holder.

9. The substrate liquid processing method of claim 8,
wherein a temperature of the heating device is equal to or lower than 80° C.
